(19) United States
(12) Patent Application Publication
(10) Pub. No.: US 2026/0118404 A1
(43) Pub. Date: Apr. 30, 2026

(54) METHODS AND APPARATUS TO IDENTIFY A STATE CHANGE OF A SWITCH

(71) Applicant: Texas Instruments Incorporated, Dallas, TX (US)

(72) Inventors: Priyanshu Pandey, Bengaluru (IN); Rejin Kanjavalappil Raveendranath, Bangalore (IN); Manojit Chakraborty, Bengaluru (IN); Asish Das, Bangalore (IN); Rajib Chatterjee, Kolkata (IN); Nikhil Goyal, Bengaluru (IN)

(21) Appl. No.: 19/371,926

(22) Filed: Oct. 28, 2025

(30) Foreign Application Priority Data
Oct. 29, 2024 (IN) 202441082655
Oct. 30, 2024 (IN) 202441083004

(51) Int. Cl. G01R 31/26

(52) U.S. Cl. CPC G01R 31/2617; G01R 31/2621

(57) ABSTRACT

An example apparatus includes: a first switch; second and third switches coupled in series; a driver configured to: receive a first control signal; provide a second control signal having an edge having a first slope to control terminals of the first and second switches based on the first control signal; and provide a third control signal having a second edge having a second slope to a control terminal of the third switch based on the first control signal, the second slope being higher than the first slope.

### CROSS-REFERENCE TO RELATED APPLICATION

This application claims the benefit of and priority to Indian Provisional Patent Application No. 202441083004, filed Oct. 30, 2024, Indian Provisional Patent Application No. 202441082655, filed Oct. 29, 2024, and Indian Provisional Patent Application No. 202441082651, filed Oct. 29, 2024, which are hereby incorporated herein by reference in their entireties.

### TECHNICAL FIELD

This description relates generally to an electronic system and method, and, in particular embodiments, to a method and apparatus to identify a state change of a switch.

### BACKGROUND

Some electrical systems include switches (e.g., power switches, transistors, power transistors, etc.) that can turn on and off to apply power (e.g., voltage and/or current) to a load. For example, charge pumps, switching amplifiers, full bridge circuits, half bridge circuits, amplifiers (e.g., class D amplifiers), all include switches that are controlled by a low voltage control signal. For example, for a p-channel transistor, when the low voltage control signal is a first voltage (e.g., 0 Volts (V)), the p-channel transistor turns on (e.g., to operate as a closed switch) to apply a high voltage to a load and, when the low voltage control signal is a second voltage (e.g., 3 V), the p-channel transistor turns off (e.g., to operate as an open switch) to prevent the high voltage from being applied to the load.

### SUMMARY

In accordance to an embodiment, an apparatus includes: a driver including: a first inverter having an input and an output; and a second inverter having an input and an output, the input of the second inverter coupled to the output of the first inverter; a first transistor of a first type, the first transistor having a first current path terminal, a second current path terminal, and a control terminal, the control terminal of the first transistor coupled to the output of the second inverter; a second transistor of the first type, the second transistor having a first current path terminal, a second current path terminal, and a control terminal, the control terminal of the second transistor coupled to the output of the second inverter and the control terminal of the first transistor, the second current path terminal of the second transistor coupled to the second current path terminal of the first transistor; and a third transistor of the first type, the third transistor having a control terminal and a first current path terminal, the control terminal of the first transistor coupled to the output of the first inverter and the input of the second inverter, the first current path terminal of the third transistor coupled to the first current path terminal of the second transistor.

In accordance to an embodiment, an apparatus includes: a first switch; second and third switches coupled in series; a driver configured to: receive a first control signal; provide a second control signal having an edge having a first slope to control terminals of the first and second switches based on the first control signal; and provide a third control signal having a second edge having a second slope to a control terminal of the third switch based on the first control signal, the second slope being higher than the first slope.

In accordance to an embodiment, a charge pump includes: a first charge pump terminal configured to be coupled to a capacitor; a second charge pump terminal coupled to a first common terminal and configured to be coupled to the capacitor; a switch having a first current path terminal, a second current path terminal, and a control terminal, the first current path terminal of the switch coupled to a second common terminal, the second current path terminal of the switch coupled to the first charge pump terminal; driver circuitry coupled to the control terminal of the switch; and feedback circuitry coupled to the control terminal of the switch and the driver circuitry, the feedback circuitry including: a first transistor having a first current path terminal, a second current path terminal, and a control terminal, the control terminal of the first transistor coupled to the driver circuitry and the control terminal of the switch, the first current path terminal of the first transistor coupled to the first current path terminal of the switch; and a comparison circuit including an input and an output, the input of the comparison circuit coupled to the second current path terminal of the first transistor.

In accordance to an embodiment, a circuit includes: a high-side transistor having a first current path terminal, a second current path terminal, and a control terminal, the first current path terminal coupled to a supply terminal; a first driver having an input and an output, the output of the first driver coupled to the control terminal of the high-side transistor; a low-side transistor having a first current path terminal, a second current path terminal, and a control terminal, the first current path terminal of the low-side transistor coupled to the second current path terminal of the high-side transistor, the second current path terminal of the low-side transistor coupled to a common terminal; a second driver having an input and an output, the output of the second driver coupled to the control terminal of the low-side transistor; and feedback circuitry coupled to the output of the first driver and the control terminal of the high-side transistor, the feedback circuitry including: a first transistor having a first current path terminal, a second current path terminal, and a control terminal, the control terminal of the first transistor coupled to the output of the first driver, the first current path terminal of the first transistor coupled to the first current path terminal of the high-side transistor; and a comparison circuit including an input and an output, the input of the comparison circuit coupled to the second current path terminal of the first transistor. 28. The circuit of claim 27, where the circuit is included in a switching regulator.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 is a block diagram of an example system for controlling a switch and identifying a stage change of the switch, according to an embodiment of the present disclosure;

FIG. 2 is a circuit implementation of a driver, a switch, and switch feedback circuitry of FIG. 1, according to an embodiment of the present disclosure;

FIG. 3A is an alternative circuit implementation of a driver, a switch, and switch feedback circuitry of FIG. 1, according to an embodiment of the present disclosure;

FIG. 3B is a timing diagram corresponding to the driver, the switch, and the feedback circuitry of FIG. 3A.

FIG. 4 is an alternative circuit implementation of a driver, a switch, and switch feedback circuitry of FIG. 1, according to an embodiment of the present disclosure;

FIG. 5 is an alternative circuit implementation of a driver, a switch, and switch feedback circuitry of FIG. 1, according to an embodiment of the present disclosure;

FIG. 6 is an alternative circuit implementation of a driver, a switch, and switch feedback circuitry of FIG. 1, according to an embodiment of the present disclosure;

FIG. 7 is an example headphone system that implements switches and switch feedback circuitry, according to an embodiment of the present disclosure;

FIG. 8 is an example circuit implementation of the charge pump of FIG. 7, according to an embodiment of the present disclosure;

FIG. 9 is an example switching amplifier that includes switches and switch feedback circuitry, according to an embodiment of the present disclosure;

FIG. 10 is an example class-D amplifier that includes switches and switch feedback circuitry, according to an embodiment of the present disclosure;

FIG. 11 is an example timing diagram illustrating a comparison of some switch feedback circuitry and the switch feedback circuitry disclosed herein with respect to average current consumption; and

FIG. 12 is an example timing diagram illustrating a comparison of some switch feedback circuitry and the switch feedback circuitry disclosed herein with respect to power consumption.

Corresponding numerals and symbols in different figures generally refer to corresponding parts unless otherwise indicated. The figures are drawn to clearly illustrate relevant aspects of preferred embodiments and are not necessarily drawn to scale.

### DETAILED DESCRIPTION

The making and using of the embodiments disclosed are discussed in detail below. It should be appreciated, however, that the present disclosure provides many applicable inventive concepts that can be embodied in a wide variety of specific contexts. The specific embodiments discussed are merely illustrative of specific ways to make and use the disclosure, and do not limit the scope of the disclosure.

The description below illustrates various specific details to provide an in-depth understanding of several example embodiments according to the description. The embodiments may be received without one or more of the specific details, or with other methods, components, materials and the like. In some cases, known structures, materials or operations are not shown or described in detail so as not to obscure the different aspects of the embodiments. References to “an embodiment” or “an example” in this description indicate that a particular configuration, structure or feature described in relation to the embodiment is included in at least one embodiment. Consequently, phrases such as “in one embodiment” or “in one example” that may appear at different points of the present description do not necessarily refer exactly to the same embodiment. Furthermore, specific formations, structures or features may be combined in any appropriate manner in one or more embodiments.

Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events.

Embodiments of the present disclosure are described in specific contexts, e.g., a headphone system. Some embodiments may be used in other applications or systems, such as amplifiers (e.g., class-D amplifiers, switching amplifiers, etc.), charge pumps, and/or any other circuit that uses a switch.

In an embodiment, circuitry is disclosed to determine/identify when a switch has switched states.

When a controller outputs a signal to turn off a switch to cause the switch to operate as an open switch, it takes time before the switch actually adjusts to the open/cutoff state. In some examples, after outputting a signal to turn off the switch, the controller outputs a second signal to turn on a different switch. However, in some systems, both switches being on at the same time may result in a short circuit that can cause current to increase to dangerous levels. Accordingly, it may be beneficial for the controller to not turn on the second switch until the first switch is fully turned off. Thus, after adjusting the state of a first switch, the controller may control output control signals to ensure that both switches are off for a duration of time (referred to as deadtime) to allow the first switch to fully turn off before turning on the second switch. The longer the deadtime, the lower the chance of a short, but the worse the performance.

In some embodiments, switch feedback circuitry can be utilized to determine when a switch changes state before the controller controls another switch to avoid short circuits. Some embodiments provide high speed, accurate, low power consumption switch feedback circuitry that identify when a switch has changed states.

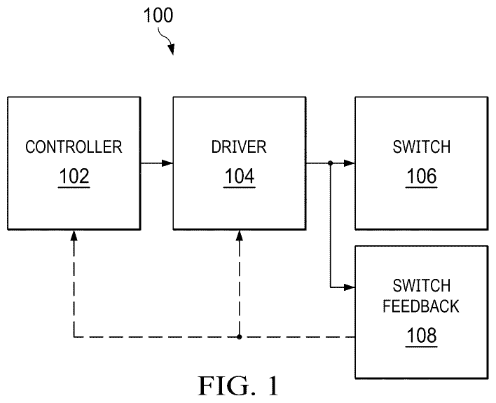

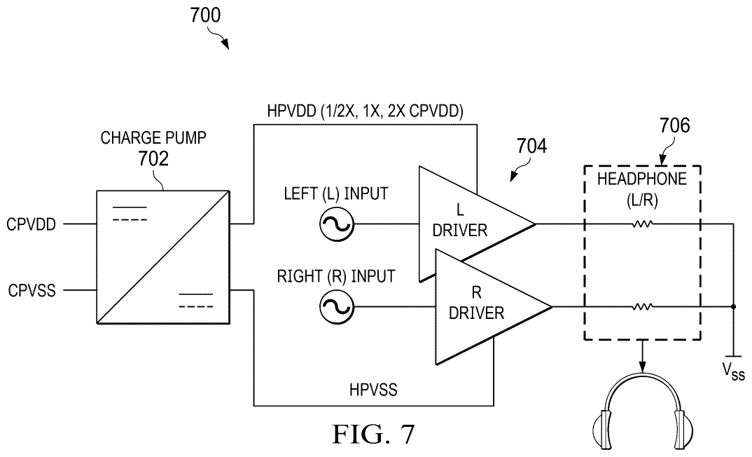

FIG. 1 is a block diagram of an example system 100, according to an embodiment of the present disclosure. The system 100 includes a controller 102, a driver 104, a switch 106, and switch feedback circuitry 108. System 100 may be implemented, e.g., in a device that uses one or more switches, as further described below in connection with FIGS. 7-10. Other implementations may also be possible.

In normal operation, the controller 102 generates a control signal to the driver 104 to control the switch 106. For example, if the switch 106 is an n-channel transistor, such as an n-channel metal oxide semiconductor (NMOS) field effect transistor (FET), the controller 102 can output the control signal as a logic low signal to cause the switch 106 to operate as an open switch (e.g., to not conduct and/or turn off) or can output the control signal as a logic high signal to cause the switch 106 to operate as a closed switch (e.g., to conduct and/or turn on). The driver 104 drives the gate terminal of the switch 106 based on the control signal. For example, when the control signal is a logic low signal, the driver 104 drives the switch 106 with a low/zero voltage/current and, when the control signal is a logic high signal, the driver 104 drives the switch 106 with a high voltage/current. The state of the switch (e.g., on/saturation/triode or off/cutoff) depends on whether the driver 104 is driving the gate terminal of the switch with a low/zero voltage/current or with a high voltage/current. The switch 106 may be coupled to a load and a supply voltage terminal (e.g., corresponding to a positive voltage supply, a negative voltage supply, or ground).

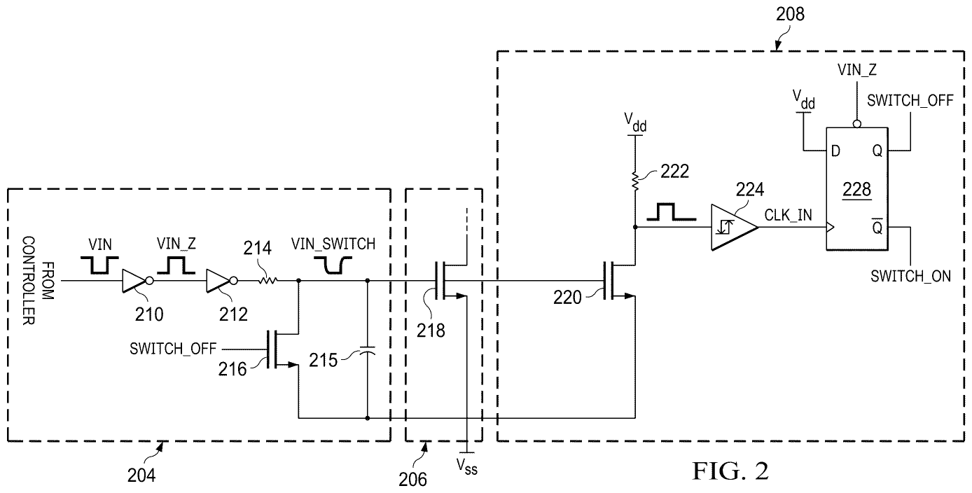

In an embodiment, when the switch 106 is conducting (e.g., in triode or saturation mode), the switch 106 couples the supply voltage terminal to the load. When the switch 106 is not conducting (e.g., in cutoff mode), the switch 106 decouples the supply voltage terminal from the load. The switch feedback circuitry 108 monitors the state of the switch 106 to output a signal after the state of the switch 106 changes (e.g., from triode/saturation to cutoff). In an embodiment, the switch feedback circuitry 108 may indicate that the switch 106 has entered a new state to the controller 102. In this manner, the controller 102 can enable another switch and limit risk of causing a short. In some examples (such as in an asynchronous mode), the controller 102 may enable a subsequent switch as soon as the controller 102 obtains the indication that the switch 106 has changed states. In some examples (such as in a synchronous mode), the controller 102 enables a subsequent switch after obtaining the indication that the switch 106 has changed states and identifying a rising and/or falling edge of a clock signal. In an embodiment, the switch feedback circuitry 108 provides the indication of a state change to a pull-down or pull up transistor, as further described below in conjunction with FIG. 2.

In some embodiments, controller 102 may be implemented as a generic or custom processor or controller coupled to a memory and configure to execute instructions in such memory. In some embodiments, controller 102 may be implemented using a field programmable gate array (FPGA). In some embodiments, controller 102 includes combinational logic, sequential logic, programmable logic (e.g., in combination with program memory), or the like, or a combination thereof. In some embodiments, controller 102 includes a state machine. In some embodiments, controller 102 includes a hardware accelerator. In some embodiments, controller 102 is implemented using (e.g., only) synthesized logic. Other implementations may also be possible.

FIG. 2 shows a schematic diagram of driver 204, switch 206, and switch feedback circuitry 208, according to an embodiment of the present disclosure. Driver 104, switch 106, and switch feedback circuitry 108 may be implemented as driver 204, switch 206, and switch feedback circuitry 208, respectively.

As shown, driver 204 includes inverters 210, 212, resistor 214, capacitor 215 (which may represent a parasitic capacitance of the transistor 218 or may be an additional capacitor), and pull-down transistor 216. Switch 206 includes transistor 218. Switch feedback circuitry 208 includes transistor 220, resistor 222, comparison circuit 224 (implemented by a buffer circuit or a Schmitt trigger buffer circuit), and flip flop 228 or other latching circuitry.

In some embodiments, feedback circuitry 208 may be used to identify when an n-channel power switch turns on.

In operation, when controller (e.g., 102) provides a logic high signal to the input of inverter 210, inverter 210 inverts the logic high signal to a logic low signal and the inverter 212 inverts the logic low voltage to a logic high voltage. Thus, the signal output by the inverter 210 is complementary (e.g., inverted) to the signal output by the inverter 212. The logic high voltage is applied to the terminal of the transistor 218 (e.g., which may be implemented as a power transistor) and the transistor 218 conducts to operate as a closed switch. Additionally, when output of the inverter 212 is a logic high, the transistor 220 (also referred to as a sense transistor) conducts, thereby grounding the input of the comparison circuit 224. When the input of the comparison circuit 224 is grounded (e.g., at 0 V and/or VSS), the comparison circuit 224 outputs a logic low voltage.

When the controller transitions from a logic high to a logic low voltage, the inverter 210 inverts the logic low signal to a logic high signal and the inverter 212 inverts the logic high voltage to a logic low voltage. The resistor 214 lowers the slope of the failing edge of the logic high voltage to logic low voltage transition of the inverter 212. Thus, the slope of the edge of the output voltage of the first inverter 210 is higher than the slope of the edge of the voltage applied to the gate terminals of the transistor 218 and transistor 220. The logic low voltage is applied to the gate terminal of the transistor 218 and the transistor 218 operates in cutoff mode to operate as an open switch. In some embodiments, transistors 218 and 220 are matched transistors (also referred to as matching pair transistors) to operate in a similar/identical manner. In an embodiment, the sense transistor 220 is a scaled replica of the power transistor 218. The state of the sense transistor 220 mirrors the state of the power transistor 218. Thus, when the power transistor 218 transitions from on (e.g., conducting to operate as a closed switch) to off (e.g., in cutoff as an open switch) or vice versa, the sense transistor 220 also transitions at the same or at a substantially similar time. Thus, when the inverter 212 output is a logic low, the transistor 220 does not conduct and operates in cutoff mode, thereby causing Vdd to be applied of the comparison circuit 224 through the resistor 222. The higher the resistance of the resistor 222, the less power that the switch feedback circuitry 208 consumes, but the slower that the switch feedback circuitry 208 reacts to a state change. Thus, the resistance can be selected to balance power consumption and speed based on the desired characteristics.

When the input of the comparison circuit 224 is high, the comparison circuit 224 outputs a logic high voltage. The output of the comparison circuit 224 is applied to the clock input of the flip flop 228 and Vdd (e.g., a high voltage) is applied to the data input of the flip flop. The first output (Q) of the flip flop corresponds to a first switch feedback terminal or a first flag terminal of the switch feedback circuitry 208 (e.g., the terminal that corresponds to the output signal that is a logic high voltage when the power transistor 218 is off). The second inverted output (Q̅) of the flip flop 228 corresponds to a second switch feedback terminal or a second flag terminal of the switch feedback circuitry 208 (e.g., the terminal that corresponds to the output signal that is a logic high voltage when the power transistor 218 is on). Accordingly, when the transistors 218, 220 transition from on to off, the comparison circuit 224 outputs a pulse that triggers the flip flop 228 to output a logic low signal at the SWITCH_ON terminal and a logic high on the SWITCH_OFF terminal. The flip flop 228 holds the logic low output on the SWITCH_ON terminal and the logic high output on the SWITCH_OFF terminal until the VIN_Z signal reduces to a logic low, which corresponds to the transistors 218, 220 transitioning back from off to on. The outputs of the flip flop 228 corresponds to the state of the transistor 218. The first output (Q) and/or the second inverted output (Q̅) can be transmitted to the controller 102 (e.g., by coupling the outputs of flip-flop 228 to controller 102) to indicate the state of the transistor 218. Because the sense transistor 220 does not connect Vdd to ground when the sense transistor 220 is off, the switch feedback circuitry 208 only consumes power when the sense transistor 220 is on. The output(s) of the flip flop 228 (e.g., at the switch feedback terminal, also referred to as the flag terminal) can be sent to the controller 102 to indicate the state and/or a stage change of the power transistor 218.

In an embodiment, the first (Q) output of comparison circuit 224 is coupled to the gate terminal of the transistor 216. In this manner, when the transistor 218 is off, the flip flop 228 outputs a high voltage at the gate terminal of the transistor 216 (e.g., via the first Q output/SWITCH_OFF terminal) causing the transistor 216 to conduct to keep the gate of the transistor 218 grounded. This helps to discharge any gate capacitance (represented by the capacitor 315) of the transistor 218 to prevent switching loss and/or avoid issues caused by a floating gate (e.g., which can pick up noise or hold residual charge that could lead to unintentionally turning on the transistor 218).

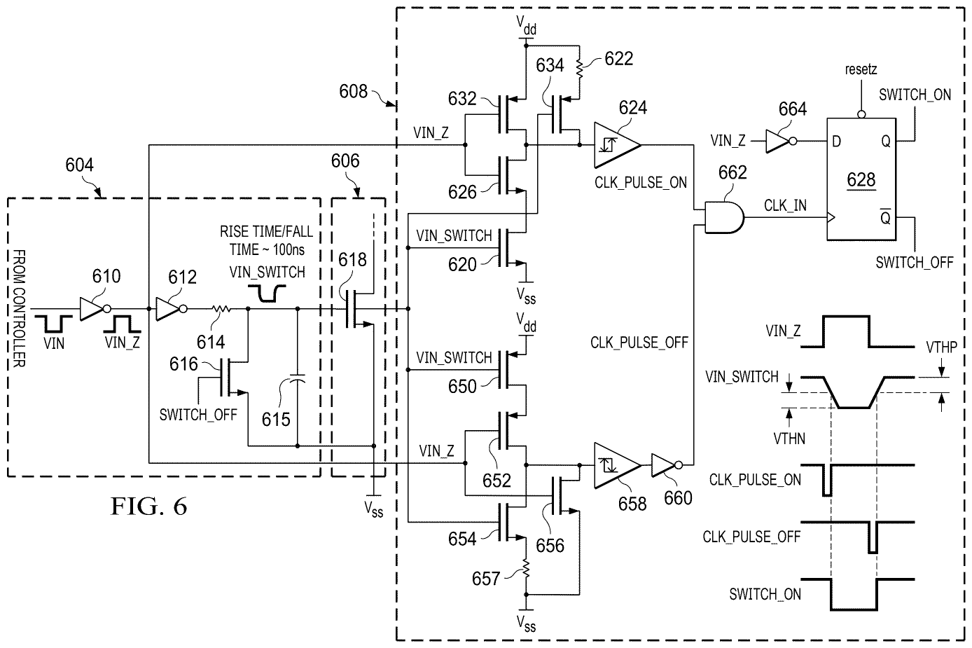

Although the switch feedback circuitry 208 determines when the transistor 218 turns off, the determination of when the transistor 218 turns on is based on the output of the controller 102, not when the transistor 218 actually turns on. However, similar circuitry can be added to or used to replace the switch feedback circuitry 208 to determine when the transistor 218 turns on or when the transistor 218 turns on and turns off, as further described below in conjunction with FIG. 6.

In some embodiments, switch feedback circuitry 208 could be coupled to a p-channel transistor to determine when the p-channel transistor turn on.

In the example of FIG. 2, the transistors 218, 220 are n-channel metal-oxide semiconductor field-effect transistors (MOSFETs), each with a gate terminal, a first drain terminal, and a second source terminal. Alternatively, the transistors 218, 220 may be n-channel field-effect transistors (FETs), n-channel insulated-gate bipolar transistors (IGBTs), n-channel junction field effect transistors (JFETs), NPN bipolar junction transistors (BJTs) or, with slight modifications, p-type equivalent devices. The gate terminal is an example of a control terminal and the source and drain terminals are examples of current path terminals. Additionally, a current path of a transistor corresponds to the path between a the source and drain of a transistor.

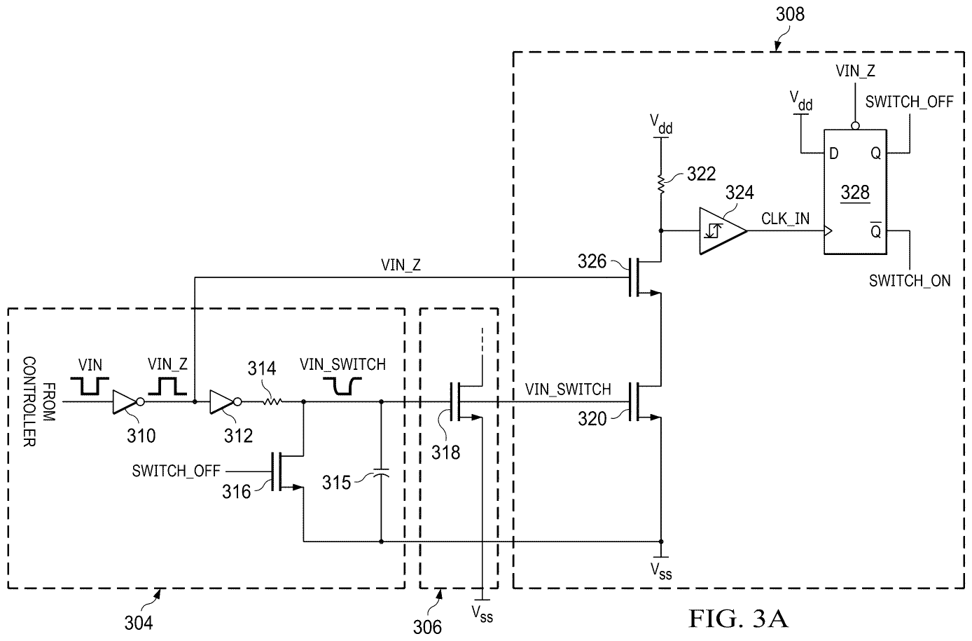

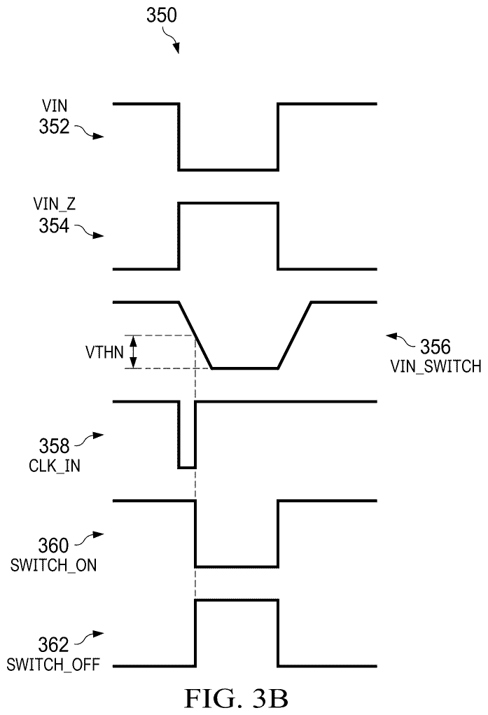

FIG. 3A shows a schematic diagram of driver 304, switch 306, and switch feedback circuitry 308, according to an embodiment of the present disclosure. Driver 104, switch 106, and switch feedback circuitry 108 may be implemented as driver 304, switch 306, and switch feedback circuitry 308, respectively.

As shown, driver 304 includes inverters 310, 312, resistor 314, capacitor 315 215 (which may represent a parasitic capacitance of the transistor 318 or may be an additional capacitor), and a pull-down transistor 316. The switch 306 includes a transistor 318. The switch feedback circuitry 308 includes transistors 320, 326, resistor 322, comparator 324 (implemented by a buffer circuit), and flip flop 328 or other latching mechanism. The driver 304, the switch 306, the sense transistor 320, and the resistor 322 of FIG. 3A operate in the same/similar manner as the driver 204, switch 206, the sense transistor 220, and the resistor 222.

In some embodiments, switch feedback circuitry 308 may be used to identify when an n-channel power switch turns on.

In an embodiment, the switch feedback circuitry 308 includes transistor 326, which is also referred to as a block transistor. The transistor 326 is controlled based on the output of the inverter 310, which is complementary to the output of the controller 102. Thus, the transistor 326 operates in cutoff mode (e.g., operating as an open switch) when the controller 102 controls the transistor 318 to operate in an on state. Additionally, as described above, the sense transistor 320 operates in cutoff mode, when voltage applied to the gate terminal of the transistor 320 is low (e.g., below a threshold voltage of the transistor 320). Thus, in some embodiments, for the switch feedback circuitry 308, the only time the switch feedback circuitry 308 consumes power is when the output of the Vin voltage is high (e.g., the VIN_Z voltage is low) and the voltage applied to the gate terminal of the sense transistor 320 is transitioning from a logic high to a logic low. Thus, in some embodiments, for a majority of the duty cycle, the switch feedback circuitry 308 is not consuming power.

Due to the addition of the block transistor 326 to further conserve power, the voltage at the input of the comparison circuit 224 temporarily adjusts from a logic high to a logic low when the transistor 318 turns off. Thus, the comparator 324 and the flip flop 328 are structured to hold a voltage indicative of the transistor 318 being off until the transistor 318 is turned back on. For example, the output of the comparator 324 is applied to the clock input of the flip flop 328 and Vdd (e.g., a high voltage) is applied to the data input of the flip flop. The first output (Q) of the flip flop 328 corresponds to a first switch feedback terminal or the flag terminal of the switch feedback circuitry 308 (e.g., the terminal that corresponds to the output signal that is a logic high voltage when the power transistor 318 is off). The second inverted output (Q̅) of the flip flop 328 corresponds to a second switch feedback terminal or the flag terminal of the switch feedback circuitry 308 (e.g., the terminal that corresponds to the output signal that is a logic high voltage when the power transistor 318 is on). Accordingly, when the transistors 318, 320 transition from on to off, the comparator 324 outputs a pulse that triggers the flip flop 328 to output a logic low signal at the SWITCH_ON terminal and a logic high on the SWITCH_OFF terminal. The flip flop 328 holds the logic low output on the SWITCH_ON terminal and the logic high on the SWITCH_OFF terminal until the VIN_Z signal reduces to a logic low, which corresponds to the transistors 318, 320 transitioning back from off to on. A timing diagram of this operation is further described below in conjunction with FIG. 3B.

In the example of FIG. 3A, the transistors 318, 320, 326 are n-channel metal-oxide semiconductor field-effect transistors (MOSFETs), each with a gate terminal, a first drain terminal, and a second source terminal. Alternatively, the transistors 318, 320, 326 may be n-channel field-effect transistors (FETs), n-channel insulated-gate bipolar transistors (IGBTs), n-channel junction field effect transistors (JFETs), NPN bipolar junction transistors (BJTs) or, with slight modifications, p-type equivalent devices.

Although the switch feedback circuitry 308 determines when the transistor 318 turns off, the determination of when the transistor 318 turns on is based on the output of the controller 102, not when the transistor 318 actually turns on. However, similar circuitry can be added to or used to replace the switch feedback circuitry 308 to determine when the transistor 318 turns on or when the transistor 318 turns on and turns off, as further described below in conjunction with FIG. 6. Additionally, the switch feedback circuitry 308 could be coupled to a p-channel power transistor to determine when the p-channel power transistor turn on.

FIG. 3B shows timing diagram 350 that corresponds to voltages at various nodes/terminals of the circuit of FIG. 3A, according to an embodiment of the present disclosure. FIG. 3B includes an input voltage 352, a VIN_Z voltage 354, a VIN_SWITCH voltage 356, a CLK_IN voltage 358, a SWITCH_ON voltage 360, and a SWITCH_OFF voltage 362. The VIN voltage 352 corresponds to the output of the controller 102 and the input of the inverter 310 at the VIN terminal of FIG. 3A. The VIN_Z voltage 354 corresponds to the output of the inverter 310 and the input of the inverter 312 at the VIN_Z terminal (also referred to as a reset input terminal) of FIG. 3A. The VIN_SWITCH voltage 356 corresponds to the gate terminal of the transistors 318, 320 2 at the VIN_SWITCH terminal of FIG. 3A. The CLK_IN voltage 358 corresponds to the output of the comparator 324 and the clock input of the flip flop 328 at the CLK_IN terminal of FIG. 3A. The SWITCH_ON voltage 360 corresponds to the inverted second (Q̅) output of the flip flop 328 at the SWITCH_ON terminal (also referred to as the flag terminal) of FIG. 3A. The SWITCH_OFF voltage 362 corresponds to the first (Q) output of the flip flop 328 at the SWITCH_OFF terminal (also referred to as the flag terminal) of FIG. 3A.

In an embodiment, initially the VIN voltage 352 is a high voltage corresponding to the transistors 318, 320 operating in an on state (e.g., as a closed switch). Accordingly, the VIN_Z voltage 354 is a logic low and the VIN_SWITCH voltage 356 is a logic high. Because the VIN_SWITCH voltage 356 is a logic high, the transistor 320 is off and the comparator 324 outputs a logic high, as shown int he CLK_IN voltage 358. Additionally, the SWITCH_ON voltage 360 is a logic high and the SWITCH_OFF voltage 362 is a logic low initially.

When the controller 102 adjusts the VIN voltage 352 from a logic high to a logic low, the VIN_Z voltage 354 adjusts from a logic low to a logic high. Accordingly, the transistor 326 is turned on while the VIN_SWITCH 356 begins to decrease. After the VIN_Z 354 rises to a logic high voltage and while the VIN_SWITCH 356 is above the threshold voltage of the transistors 318, 320, both the transistors 326 and 320 are on causing the input of the comparator 324 to be short to ground, which decreases the CLK_IN voltage 358. When the VIN_SWITCH 356 drops below the threshold voltage of the transistors 318, 320, the transistors 318, 320 turn off, causing the input of the comparator 324 to be shorted to VDD, which causes the CLK_IN voltage 358 to rise. The quick fall and rise of the CLK_IN voltage 358 acts as a clock pulse to cause the flip flop 328 to adjust the SWITCH_ON voltage 360 from a logic high to a logic low and adjusts the SWITCH_OFF voltage 362 from a logic low to a logic high. The flip flop 328 holds the logic low for the SWITCH_ON voltage 360 and holds the logic high for the SWITCH_OFF voltage 362 until the VIN_Z voltage 354 decreases to a logic low voltage, which causes the flip flop 328 to reset the SWITCH_ON voltage 360 back to a logic high voltage and to reset the SWITCH_OFF voltage 362 back to a logic low voltage.

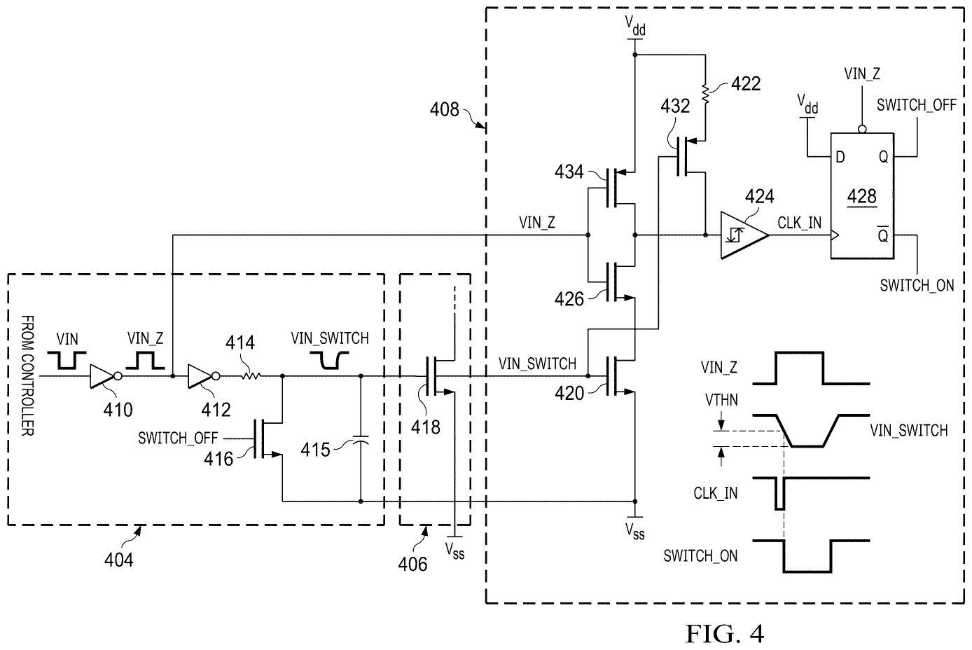

FIG. 4 shows a schematic diagram of driver 404, switch 406, and switch feedback circuitry 408, according to an embodiment of the present disclosure. Driver 104, switch 106, and switch feedback circuitry 108 may be implemented as driver 404, switch 406, and switch feedback circuitry 408, respectively.

As shown, driver 404 includes inverters 410, 412, resistor 414, capacitor 415 (which may represent a parasitic capacitance of the transistor 418 or may be an additional capacitor), and pull-down transistor 416. The switch 406 includes a transistor 418. The switch feedback circuitry 408 includes transistors 420, 426, a resistor 422, a comparator 424 (implemented by a buffer circuit), a flip flop 428 or other latching mechanism, a block transistor 432, and a reset transistor 434. The driver 404, the switch 406, the sense transistor 420, the resistor 422, the comparator 424, the transistor 426, and the flip flop 428 operate in the same/similar manner as the driver 304, switch 306, the sense transistor 320, the resistor 322, the comparator 324, the transistor 326, the flip flop 328 of FIG. 3A.

In some embodiments, feedback circuitry 408 may be used to identify when an n-channel power switch turns on.

In an embodiment, the switch feedback circuitry 408 includes the block transistor 432 and the reset transistor 434 to further reduce the amount of time that the switch feedback circuitry 408 consumes power. The block transistor 432 is controlled by the VIN_SWITCH voltage that is applied to the gate terminals of the transistors 418, 420. For example, when the VIN_SWITCH voltage is a low voltage (e.g., below a threshold voltage of the transistor 432), the block transistor 432 conducts to turn on and operate as a closed switch. When the VIN_SWITCH voltage is a logic high (e.g., above the threshold voltage of the transistor 432), the block transistor 432 does not conduct to turn off and operates as an open switch in cutoff mode. As described above in conjunction with FIG. 3A, the block transistor 426 causes the switch feedback circuitry 408 to only draw power when the output voltage of the inverter 410 (e.g., the VIN_Z voltage) is a logic high and the voltage applied to the gate terminals of the transistors 418, 420 (e.g., the VIN_SWITCH) is decreasing between a logic high voltage and a logic low voltage. Additionally, because the block transistor 432 decouples VDD from VSS (ground) when the transistors 432 is not conducting (e.g., when VIN_SWITCH voltage is above the threshold voltage of the transistor 432), the switch feedback circuitry 408 does not start to consume power until the VIN_SWITCH power reaches VDD−|VTHP|, where VTHP is the threshold voltage of the transistor 432. Thus, the switch feedback circuitry 408 consumes less power than the switch feedback circuitry 308 of FIG. 3A, which allows a designer to select a smaller resistance for the resistor 422, resulting in faster state detection than the switch feedback circuitry 308 at the same or similar power consumption as the switch feedback circuitry 308 or the same state detection speed as the switch feedback circuitry 308 at a lower power consumption as the switch feedback circuitry 308.

In an embodiment, the reset transistor 434 is controlled by the VIN_Z voltage output by the inverter 410. The reset transistor 434 is controlled by the VIN_Z voltage output by the inverter 410. For example, when the VIN_Z voltage is a low voltage, the reset transistor 434 conducts to turn on and operate as a closed switch. When the VIN_Z voltage is a logic high, the reset transistor 434 does not conduct to turn off and operates as an open switch in cutoff mode. Thus, the reset transistor 434 operates as a reset to maintain Vdd at the input of the comparator 424 when the VIN_Z voltage is low.

In the example of FIG. 4, the transistors 418, 420, 426, are n-channel metal-oxide semiconductor field-effect transistors (MOSFETs), each with a gate terminal, a first drain terminal, and a second source terminal. Alternatively, the transistors 418, 420, 426 may be n-channel field-effect transistors (FETs), n-channel insulated-gate bipolar transistors (IGBTs), n-channel junction field effect transistors (JFETs), NPN bipolar junction transistors (BJTs) or, with slight modifications, p-type equivalent devices. In the example of FIG. 4, the transistors 432, 434 are p-channel MOSFETs, each with a gate terminal, a first source terminal, and a second drain terminal. Alternatively, the transistors 432, 434 may be p-channel FETs, p-channel IGBTs, p-channel JFETs, PNP BJTs, or, with slight modifications, N-type equivalent devices.

Although the switch feedback circuitry 408 determines when the transistor 418 turns off, the determination of when the transistor 418 turns on is based on the output of the controller 102, not when the transistor 418 actually turns on. However, similar circuitry can be added to or used to replace the switch feedback circuitry 408 to determine when the transistor 418 turns on or when the transistor 418 turns on and turns off, as further described below in conjunction with FIG. 6. Additionally, the switch feedback circuitry 408 could be coupled to a p-channel power transistor to determine when the p-channel power transistor turns on.

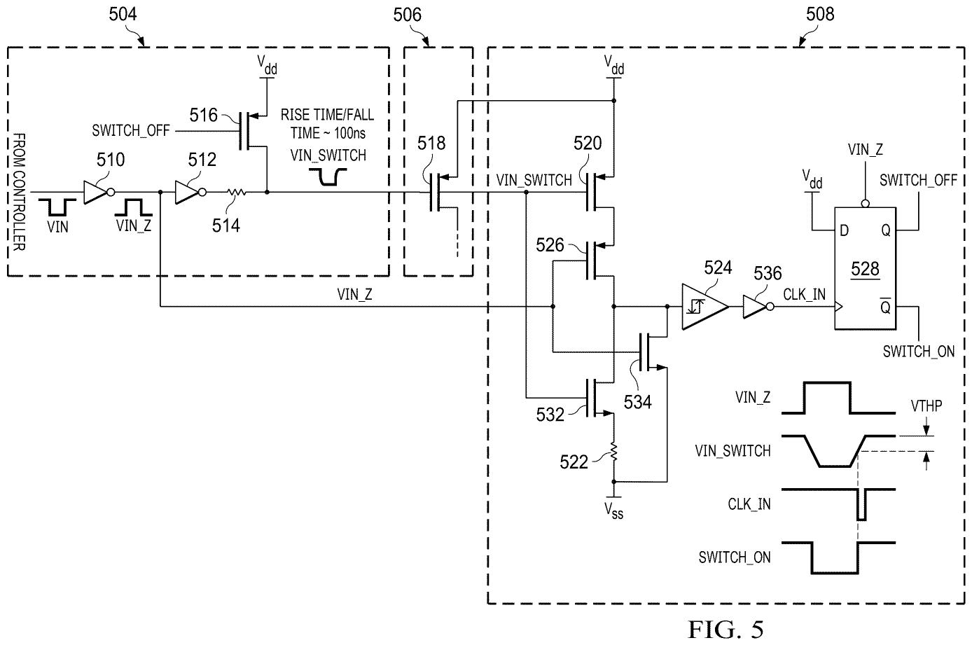

FIG. 5 shows a schematic diagram of driver 504, switch 506, and feedback circuitry 508, according to an embodiment of the present disclosure. Driver 104, switch 106, and switch feedback circuitry 108 may be implemented as driver 504, switch 506, and switch feedback circuitry 508, respectively.

As shown, driver 504 includes inverters 510, 512, resistor 514, capacitor 515 (which may represent a parasitic capacitance of the transistor 418 or may be an additional capacitor), and a pull-down transistor 516. The switch 506 includes a transistor 518. The switch feedback circuitry 508 includes transistors 520, 526, a resistor 522, a comparison circuit 524 (implemented by a buffer circuit), a flip flop 528 or other latching mechanism, a block transistor 532, a reset transistor 534, and an inverter 536. Although the switch feedback circuitry 508 is similar to the switch feedback circuitry 408 of FIG. 4, in that both switch feedback circuitries 408, 508 includes two blocking transistors and a reset transistor, the switch feedback circuitry 508 FIG. 5 may be implemented with a single block transistor, similar to the switch feedback circuitry 308, or with no block/reset transistor, similar to the switch feedback circuitry 208.

In some embodiments, switch feedback circuitry 508 may be used to identify when a p-channel power switch turns on, The driver 504, the switch 506, the sense transistor 520, the resistor 522, the comparison circuit 524, the transistor 526, and the flip flop 528 of FIG. 5 operate in the same/similar manner as the driver 404, switch 406, the sense transistor 420, the resistor 422, the comparator 424, the transistor 426, the flip flop 428. However, the transistor 518 is a p-channel transistor as opposed to the n-channel transistor 218, 318, 418. Accordingly, the transistor 516 is also a p-channel transistor that can be controlled to pull the gate terminal of the transistor 518 to Vdd when the transistor 518 has turned off.

In an embodiment, the switch feedback circuitry 508 operates in a similar manner to the switch feedback circuitry 408. However, because the transistor 518 is a p-channel transistor, the supply terminals are flipped and the type of the transistors 520, 526, 532, 534 are changed. For example, the transistors 520, 526 are p-channel transistor, as opposed to the n-channel transistors 420, 426, and the transistors 532, 534 are n-channel transistors, as opposed to the p-channel transistors 432, 434. Also, because the power transistor 518 is a p-channel transistor, the power transistor 518 turns on when the voltage at the gate terminal of the transistor 518 is a low voltage (e.g., below a threshold voltage of the power transistor 518), the inverter 536 inverts the output of the comparison circuit 524 to generate a clock pulse when the VIN_SWITCH voltage is below the threshold voltage of the transistor 518 and the VIN_Z voltage is a logic low voltage, thereby identifying when the power transistor 518 turns on.

In the example of FIG. 5, the transistors 532, 534 are n-channel metal-oxide semiconductor field-effect transistors (MOSFETs), each with a gate terminal, a first drain terminal, and a second source terminal. Alternatively, the transistors 532, 534 may be n-channel field-effect transistors (FETs), n-channel insulated-gate bipolar transistors (IGBTs), n-channel junction field effect transistors (JFETs), NPN bipolar junction transistors (BJTs) or, with slight modifications, p-type equivalent devices. In the example of FIG. 5, the transistors 518, 520, 526 are p-channel MOSFETs, each with a gate terminal, a first source terminal, and a second drain terminal. Alternatively, the transistors 518, 520, 526 may be p-channel FETs, p-channel IGBTs, p-channel JFETs, PNP BJTs, or, with slight modifications, N-type equivalent devices.

Although the switch feedback circuitry 508 determines when the transistor 518 turns off, the determination of when the transistor 518 turns on is based on the output of the controller 102, not when the transistor 518 actually turns on. However, similar circuitry can be added to or used to replace the switch feedback circuitry 508 to determine when the transistor 518 turns on or when the transistor 518 turns on and turns off, as further described below in conjunction with FIG. 6. Additionally, the switch feedback circuitry 508 could be coupled to an n-channel power transistor to determine when the n-channel power transistor turns on, as further described below in conjunction with FIG. 6.

FIG. 6 shows a schematic diagram of driver 604, switch 606, and feedback circuitry 608, according to an embodiment of the present disclosure. Driver 104, switch 106, and switch feedback circuitry 108 may be implemented as driver 604, switch 606, and switch feedback circuitry 608, respectively.

As shown, driver 604 includes inverters 610, 612, resistor 614, capacitor 615 (which may represent a parasitic capacitance of the transistor 618 or may be an additional capacitor), and pull-down transistor 616. The switch 606 includes a transistor 618. The switch feedback circuitry 608 includes transistors 620, 626, a resistor 622, a comparison circuit 624 (implemented by a buffer circuit), a flip flop 628 or other latching mechanism, a block transistor 632, a reset transistor 634, transistors 650, 652, 654, 656, a resistor 657, a comparison circuit 548, an inverter 660, a logic AND gate 662, and an inverter 664. The driver 604, the switch 606, the sense transistor 620, the resistor 622, the comparison circuit 624, the transistor 626, the flip flop 628, and the transistors 632, 634 operate in the same/similar manner as the driver 404, switch 406, the sense transistor 420, the resistor 422, the comparator 424, the transistor 426, the flip flop 428, and the transistors 432, 434. The transistors 650, 652, 654, 656, the resistor 657, the comparison circuit 658, and the inverter 660 operate in the same/similar manner as the transistor 520, 526, 532, 534, the resistor 522, the comparison circuit 524, and the inverter 536.

In some embodiments, switch feedback circuitry 608 may be used to identify when an n-channel power switch turns on and turns off.

As described above in conjunction with FIG. 4, the components 620, 622, 624, 626, 632, 634 generate a pulse signal whenever the transistor 618 turns off. Likewise, the components 650, 652, 654, 656, 657, 658, 660 generate a pulse whenever the transistor 618 turns on, as described above in conjunction with FIG. 5. The logic AND gate 662 combines the clock signal from the comparison circuitry 624 with the clock signal from the inverter 660 to generate the CLK_IN output, which pulses when the transistor 618 turns off and pulses when the transistor 618 turns on. The output of the logic AND gate 662 operates as the clock signal for the flip flop 628. Because the logic AND gate 662 of the switch feedback circuitry 608 of FIG. 6 pulses when the transistor 618 turns on and off, the D input of the flip flop 628 toggles for every state change so that the sampled data corresponds to the correct pulse. In this manner, the flip flop 628 outputs a high voltage on the SWITCH_ON terminal and a low voltage on the SWITCH_OFF terminal when the transistor 618 turns on and the flip flop 628 outputs a low voltage on the SWITCH_ON terminal and a high voltage on the SWITCH_OFF terminal when the transistor 618 turns off.

In the example of FIG. 6, the transistors 618, 620, 626, 654, 656 are n-channel metal-oxide semiconductor field-effect transistors (MOSFETs), each with a gate terminal, a first drain terminal, and a second source terminal. Alternatively, the transistors 618, 620, 626, 654, 656 may be n-channel field-effect transistors (FETs), n-channel insulated-gate bipolar transistors (IGBTs), n-channel junction field effect transistors (JFETs), NPN bipolar junction transistors (BJTs) or, with slight modifications, p-type equivalent devices. In the example of FIG. 6, the transistors 632, 634, 650, 652 are p-channel MOSFETs, each with a gate terminal, a first source terminal, and a second drain terminal. Alternatively, the transistors 632, 634, 650, 652 may be p-channel FETs, p-channel IGBTs, p-channel JFETs, PNP BJTs, or, with slight modifications, N-type equivalent devices.

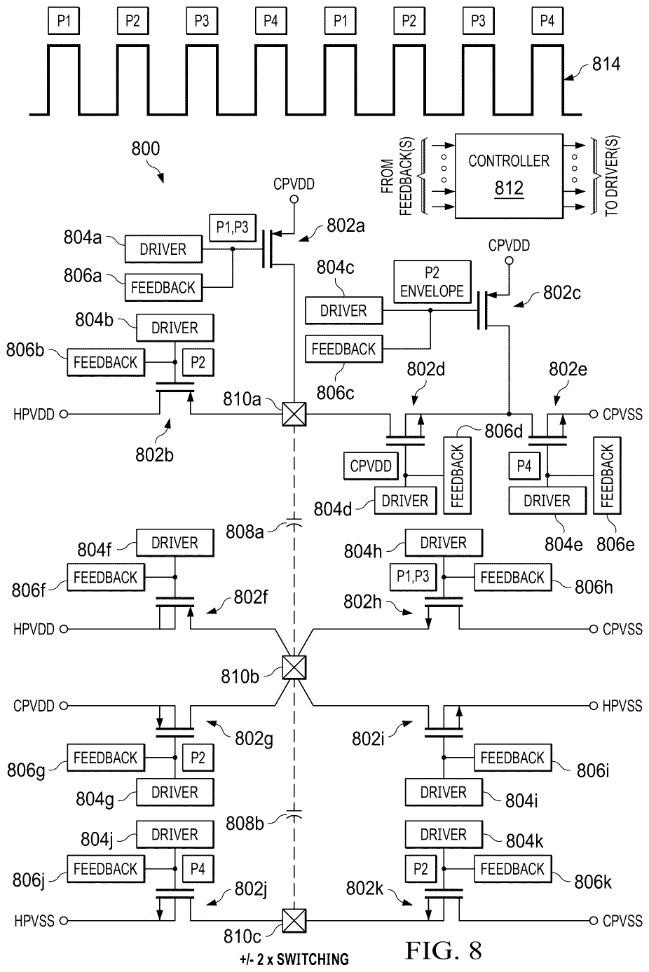

FIG. 7 illustrates headphone system 700, according to an embodiment of the present disclosure. Headphone system 700 includes charge pump 702, driver 704 (also referred to as a speaker driver), and headphones 706. Any one of, or variation of, the switch feedback circuitries 108, 208, 308, 408, 508, 608 of FIGS. 1-6 could be implemented in the charge pump 702 and/or the drivers 704. The charge pump 702 generates voltages at the first common (e.g., output) terminals HPVDD and HPVSS terminals based on voltages at the common (e.g., supply or input) terminals (CPVDD and CPVSS). The drivers 704 use the generated voltages to drive the headphones 706. For example, the driver 704 obtains low power input signals (e.g., a left input signal and a right input signal) and amplifies the low power input signals based on the voltages output by the charge pumps on the HPVDD and HPVSS terminals. An example implementation of the charge pump 702 is further described below in conjunction with FIG. 8. Other implementations may also be possible.

FIG. 8 shows a schematic diagram of charge pump 800, according to an embodiment of the present disclosure. Charge pump 702 may be implemented as charge pump 800. Charge pump 800 includes switches 802a-k, drivers 804a-j, switch feedback circuitries 806a-j, capacitors 808a-c, charge pump terminals 810a-c, and a controller 812. Any one of the drivers 804a-j may be implemented by one or more of the drivers 104, 204, 304, 404, 504, 604 of FIGS. 1-6. Any one of the switch feedback circuitries 806a-j may be implemented by any one or variation of the switch feedback circuitries 108, 208, 308, 408, 508, 608 of FIGS. 1-6. The controller 812 may be implemented by the controller 102 of FIG. 1. Other implementations may also be possible.

In one embodiment, the controller 812 may output control signal to the drivers 804a-j to turn on or off the transistors 802a-j based on control signal(s) from the controller 812 (e.g., represented by example signal 814). The controller 812 can output a signal to keep the switch 802d conducting throughout operation. During the P1/P3 pulse generation, the controller 812 can output control signals to turn on the switches 802a, 802h and to turn off the remaining switches. For the P2 pulse generation, the controller 812 outputs control signals to turn on the switches 802b, 802g, 802k and turn off the remaining switches, For the P4 pulse generation, the controller 812 can output control signals to turn on the switches 802e, 802j. The control of the switches 802a-j determines how the capacitors 808a-c are charge/discharged and what the output voltage is. The switch feedback circuitries 806a-k output switch state indication signals (e.g., feedback) to the controller 812 to avoid the controller 812 from turning on two or more transistors 802a-k and creating an unintentional short between any ground or supply (e.g., CPVSS to HPVSS, CPVDD to HPVDD, etc.). Thus, the controller 812 can, based on the feedback from all of the switch feedback circuitries 806a-k, appropriately control the switches 802a-k without unintentionally creating a short. Additionally, the controller 812 can output a control signal to turn on the switch 802c during a duration of time referred to as the P2 envelope. The P2 envelope duration spans over the P2 pulse generation, the deadtime between P1/P2, the deadtime between P2/P3, and for part of both P1 and P3. The controller 812 turns on the switch 802c for the P2 envelope to act as a cover on top of particular phases to increase reliability of the charge pump 800.

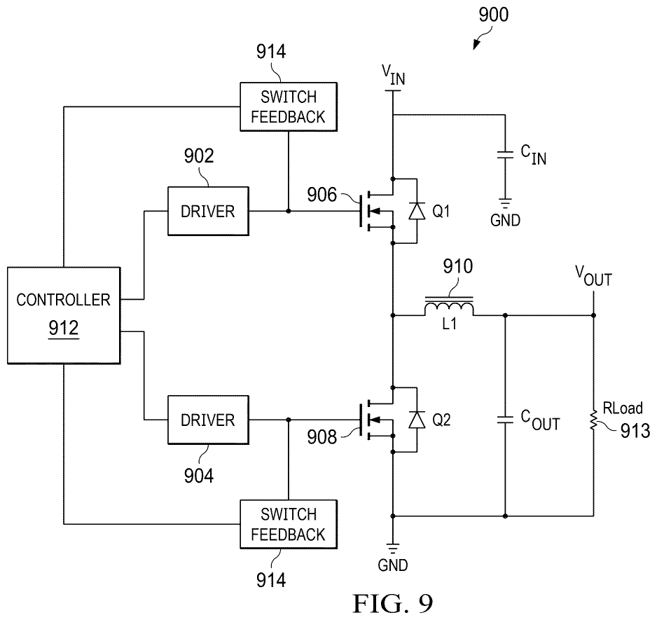

FIG. 9 shows a schematic diagram of switching regulator 900, according to an embodiment of the present disclosure. The switching regulator 900 includes drivers 902, 904, power transistors 906, 908, inductor 910, controller 912, load 913, and switch feedback circuitries 914. Any one of the drivers 902, 904 may be implemented by one or more of the drivers 104, 204, 304, 404, 504, 604 of FIGS. 2-6. Any one of the switch feedback circuitries 914 may be implemented by any one or variation of the switch feedback circuitries 108, 208, 308, 408, 508, 608 of FIGS. 1-6. Other implementations may also be possible.

The controller 912 outputs two control signals (e.g., pulse width modulated signals) to the drivers 902, 904 to turn on and off the transistors 906, 908 to charge or discharge the inductor 910 to provide a regulated voltage to the load 913. To ensure that the transistors 906, 908 are not both turned on at the same time (corresponding to a short to ground), the switch feedback circuitries 914 can provide a signal to the controller 912 when the corresponding transistor 906, 908 has changed from on to off. Accordingly, the controller 912 can prevent turning on the transistor 906 until the switch feedback circuitry 914 provides a signal to indicate that the transistor 908 is off and vice versa.

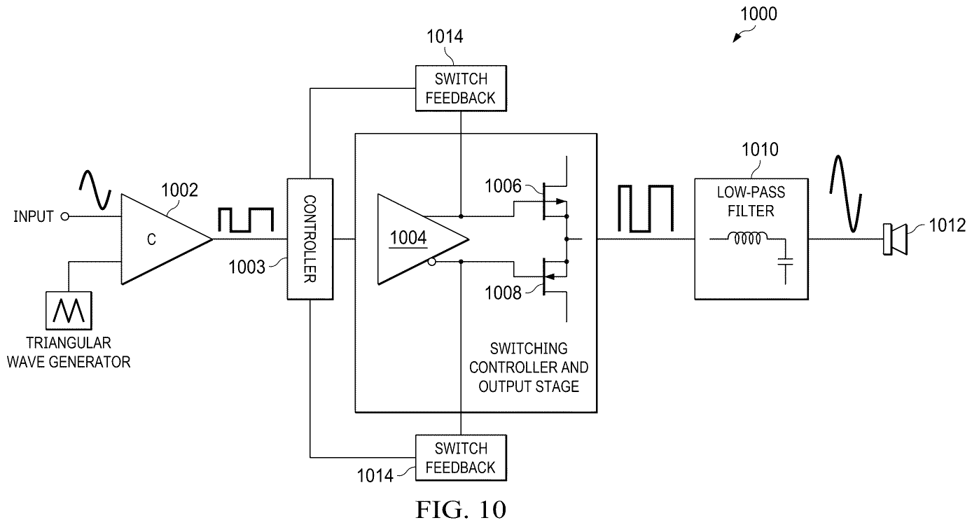

FIG. 10 shows a schematic diagram of class D amplifier 1000, according to an embodiment of the present disclosure. The class D amplifier 1000 includes comparator 1002, controller 1003, driver 1004, power transistors 1006, 1008, low pass filter 1010, speaker 1012, and switch feedback circuitries 1014. Any one of the drivers 1004 may be implemented by one or more of the drivers 104, 204, 304, 404, 504, 604 of FIGS. 1-6. Any one of the switch feedback circuitries 1014 may be implemented by any one or variation of the switch feedback circuitries 108, 208, 308, 408, 508, 608 of FIGS. 1-6. Other implementations may also be possible.

The input of the class D amplifier 1000 is an analog signal (e.g., an analog audio signal). The comparator 1002 compares the input analog signal to a triangle wave to generate a pulse width modulated signal representative of the input analog signal. The controller 1003 controls the driver 1004 based on the pulse modulated signal to control the high-side transistor 1006 and the low-side transistor 1008 using two output control signals. The controller receives feedback from the switch feedback circuitries 1014 and controls the driver 1004 to output the two output control signals such that either the transistor 1006 is conducting or the transistor 1008 is conducting, but not at the same time. When the transistor 1006 is conducting, a high voltage is output to the filter 1010, and, when the transistor 1008 is conducting, a low voltage is output to the filter 1010. The switch feedback circuitries 1014 output an off indication signal to the driver 1004, which prevents the driver 1004 from driving one of the transistors 1006, 1008 while the other transistor is still on.

Although the driver 1004 in FIG. 10 is a single component, in an embodiment, the driver 1004 may be broken up into a first driver and a second driver. The switch feedback circuitries 1014 determine when the transistor 1006, 1008 have turned off in response to the driver 1004 outputting a signal to turn off the transistor 1006, 1008. The first driver to driver the transistor 1006, the second driver to driver the transistor 1008, and the controller 1003 to, based on a signal from the switch feedback circuitries 1014, control the drivers to ensure that the two drivers are not on or conducting at the same time (e.g., to avoid a short to ground). The filter 1010 is a low pass filter that can be used to attenuate the high frequency content (e.g., noise) from the output signal from the transistors 1006, 1008. The filtered output signal is applied to the speaker 1012 to generate an amplified output (e.g., audio).

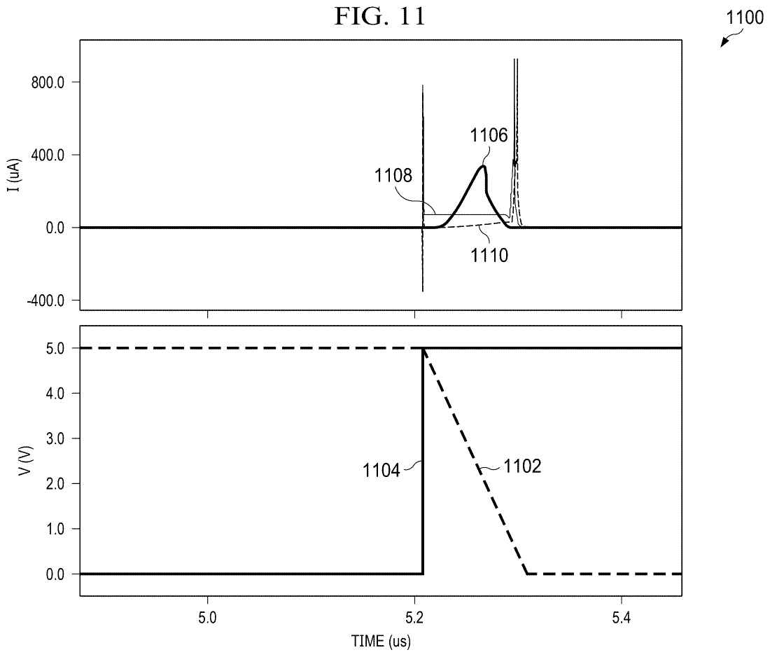

FIG. 11 illustrates an example timing diagram 1100 that illustrates a comparison of a current profile of some switch feedback circuitries to the current profile (e.g., corresponding to power consumption) of the switch feedback circuitries of examples disclosed herein, according to an embodiment of the present disclosure. FIG. 11 includes an example VIN_SWITCH voltage 1102, an example VIN_Z voltage 1104, and example current profiles 1106, 1108, 1110. The VIN_SWITCH voltage 1102 corresponds to the voltage applied to the switches 106, 206, 306, 406, 506, 606 of FIGS. 1-6. The VIN_Z voltage 1104 corresponds to the voltage output by the inverters 210, 310, 410, 510, 610 of FIGS. 1-6. The current profile 1106 corresponds to a current profile of a conventional switch feedback circuit that uses a Schmitt trigger as a comparator. The current profile 1106 corresponds to a current profile of the switch feedback circuitry 308 of FIG. 3A. The current profile 1108 corresponds to a current profile of the of the switch feedback circuit 408, 508 of FIGS. 4 and/or 5.

After the VIN_Z voltage 1104 increases from a low voltage to a high voltage, the VIN_SWITCH voltage 1102 begins to decrease from a high voltage to a low voltage, eventually causing a transistor to turn off. During this time, the first current profile 1106 consumes a large amount of current corresponding to high power consumption. For example, the first current profile 1106 corresponds to an average of 7.5 micro amperes (uA) of current consumption. The second and third current profiles 1108, 1110 have more stable and lower current consumption. For example, the second current profile 1108 corresponds to an average of 3.5 uA of current consumption (e.g., less than half the current consumption of the conventional switch feedback circuit) and the third current profile 1110 corresponds to an average of 1.5 uA of current consumption) (e.g., one fifth of the current consumption of the conventional switch feedback circuit). Thus, examples disclosed herein result in less power consumption than conventional techniques.

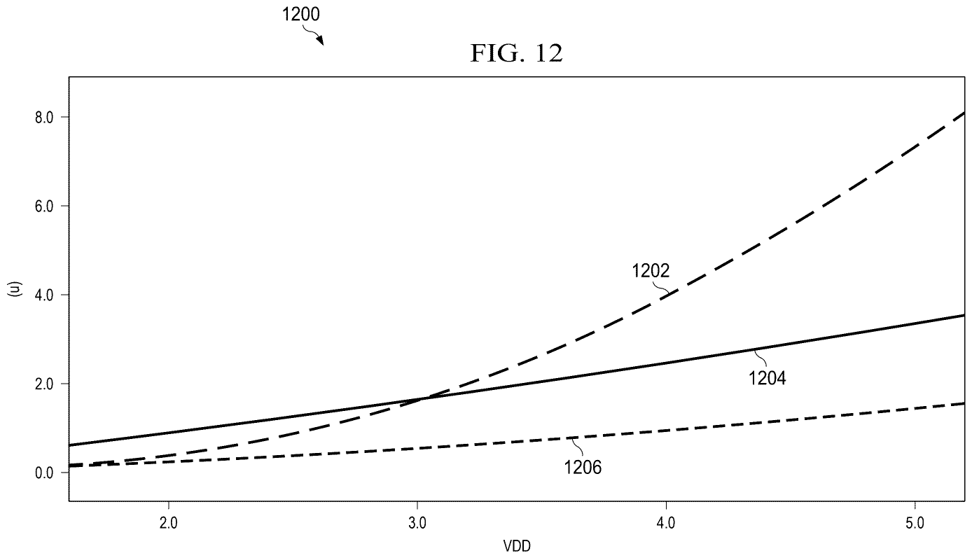

FIG. 12 illustrates an example timing diagram 1200 that illustrates a comparison of a current profile with respect to voltage supply of some switch feedback circuitries to the current profile (e.g., which corresponds to power consumption) of the switch feedback circuitries of examples disclosed herein, according to an embodiment of the present disclosure. FIG. 12 includes example current profiles 1202, 1204, 1206. The current profile 1202 corresponds to a current profile of a conventional switch feedback circuit that uses a Schmitt trigger as a comparator. The current profile 1204 corresponds to a current profile of the switch feedback circuitry 308 of FIG. 3A. The current profile 1206 corresponds to a current profile of the of the switch feedback circuit 408, 508 of FIGS. 4 and/or 5.

As shown in the timing diagram 1200, when the voltage supply is low (e.g., below 2 V), the current profiles 1202, 1204, 1206 are all similar. However, as the voltage supply increases, the rate of change of the current profile 1202 is much higher than the rate of change of the current profiles 1204, 1206. Thus, the power savings is amplified for systems with higher voltage sources (e.g., voltage sources above 3 V).

While an example manner of implementing the driver 104 and the switch feedback circuitry 108 of FIG. 1 is illustrated in FIGS. 2-6, one or more of the elements, processes, and/or devices illustrated in FIGS. 2-6 may be combined, divided, re-arranged, omitted, eliminated, and/or implemented in any other way. Further, the controller 102, the driver 104, the switch 106, and/or the switch feedback circuitry 108 of FIGS. 1-6, may be implemented by hardware alone or by hardware in combination with software and/or firmware. Thus, for example, any of the controller 102, the driver 104, the switch 106, and/or the switch feedback circuitry 108 of FIGS. 1-6, could be implemented by programmable circuitry, processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), vision processing units (VPUs), and/or field programmable logic device(s) (FPLD(s)) such as FPGAs in combination with machine readable instructions (e.g., firmware or software). Further still, the controller 102, the driver 104, the switch 106, and/or the switch feedback circuitry 108 of FIGS. 1-6 may include one or more elements, processes, and/or devices in addition to, or instead of, those illustrated in FIGS. 1-6, and/or may include more than one of any or all of the illustrated elements, processes and devices.

Example embodiments of the present disclosure are summarized here. Other embodiments can also be understood from the entirety of the specification and the claims filed herein.

Example 1. An apparatus including: a driver including: a first inverter having an input and an output; and a second inverter having an input and an output, the input of the second inverter coupled to the output of the first inverter; a first transistor of a first type, the first transistor having a first current path terminal, a second current path terminal, and a control terminal, the control terminal of the first transistor coupled to the output of the second inverter; a second transistor of the first type, the second transistor having a first current path terminal, a second current path terminal, and a control terminal, the control terminal of the second transistor coupled to the output of the second inverter and the control terminal of the first transistor, the second current path terminal of the second transistor coupled to the second current path terminal of the first transistor; and a third transistor of the first type, the third transistor having a control terminal and a first current path terminal, the control terminal of the first transistor coupled to the output of the first inverter and the input of the second inverter, the first current path terminal of the third transistor coupled to the first current path terminal of the second transistor.

Example 2. The apparatus of example 1, where the second transistor and the first transistor are a matching pair of transistors.

Example 3. The apparatus of one of examples 1 or 2, where the first transistor and the second transistor are n-channel metal oxide semiconductor transistors and the second current path terminals of the first and second transistors are source terminals.

Example 4. The apparatus of one of examples 1 to 3, further including a resistor coupled between the output of the second inverter and the control terminals of the first and second transistors.

Example 5. The apparatus of one of examples 1 to 4, further including a comparison circuit including an input and an output, the input of the comparison circuit coupled to the first current path terminal of the third transistor.

Example 6. The apparatus of one of examples 1 to 5, further including a flip flop having a clock input coupled to the output of the comparison circuit.

Example 7. The apparatus of one of examples 1 to 6, where the flip flop has a data input coupled to a supply voltage terminal, and a reset input coupled to the output of the first inverter, the input of the second inverter, and the control terminal of the first transistor.

Example 8. The apparatus of one of examples 1 to 7, further including a resistor coupled between the supply voltage terminal and the second current path terminal of the third transistor.

Example 9. The apparatus of one of examples 1 to 8, where the comparison circuit is a Schmitt Trigger buffer.

Example 10. The apparatus of one of examples 1 to 9, where the comparison circuit includes an inverter.

Example 11. The apparatus of one of examples 1 to 10, further including: a fourth transistor of a second type, the fourth transistor having a control terminal, a first current path terminal, and a second current path terminal, the control terminal of the fourth transistor coupled to the control terminal of the third transistor, the output of the first inverter, and the input of the second inverter, the second current path terminal of the fourth transistor coupled to the input of the comparison circuit; and a fifth transistor of the second type, the fifth transistor having a control terminal, a first current path terminal, and a second current path terminal, the control terminal of the fifth transistor coupled to the control terminals of the first and second transistors and the output of the second inverter, the first current path terminal of the fifth transistor coupled to the first current path terminal of the fourth transistor, and the second current path terminal of the fifth transistor coupled to the input of the comparison circuit.

Example 12. The apparatus of one of examples 1 to 11, where the first type is n-type, and where the second type is p-type.

Example 13. The apparatus of one of examples 1 to 12, further including a resistor coupled between the first current path terminal of the fourth transistor and the first current path terminal of the fifth transistor.

Example 14. The apparatus of one of examples 1 to 13, further including a fourth transistor having a first current path terminal and a second current path terminal, the first current path terminal of the fourth transistor coupled to the control terminals of the first and second transistors, the second current path terminal of the fourth transistor coupled to the second current path terminals of the first and second transistors.

Example 15. The apparatus of one of examples 1 to 14, where the first transistor and the second transistor are p-channel transistors.

Example 16. An apparatus including: a first switch; second and third switches coupled in series; a driver configured to: receive a first control signal; provide a second control signal having an edge having a first slope to control terminals of the first and second switches based on the first control signal; and provide a third control signal having a second edge having a second slope to a control terminal of the third switch based on the first control signal, the second slope being higher than the first slope.

Example 17. The apparatus of example 16, where the second and third control signals are complementary signals.

Example 18. The apparatus of one of examples 16 or 17, further including: a comparison circuit having an input coupled to the third switch; and a flag terminal configured to provide a voltage indicative of a state of the first switch based on an output of the comparison circuit.

Example 19. The apparatus of one of examples 16 to 18, further including a fourth switch coupled to a control terminal of the first switch, the fourth switch having a control terminal coupled to the flag terminal.

Example 20. The apparatus of one of examples 16 to 19, further including a controller configured to adjust the first control signal responsive to the voltage.

Example 21. The apparatus of one of examples 16 to 20, where the controller is configured to adjust the first control signal responsive to the voltage and an edge of a clock signal.

Example 22. The apparatus of one of examples 16 to 21, where the second and third switches are n-type transistors, where the second control signal has a lower slope than the first control signal, and where the third control signal is an inverted version of the first control signal.

Example 23. A charge pump including: a first charge pump terminal configured to be coupled to a capacitor; a second charge pump terminal coupled to a first common terminal and configured to be coupled to the capacitor; a switch having a first current path terminal, a second current path terminal, and a control terminal, the first current path terminal of the switch coupled to a second common terminal, the second current path terminal of the switch coupled to the first charge pump terminal; driver circuitry coupled to the control terminal of the switch; and feedback circuitry coupled to the control terminal of the switch and the driver circuitry, the feedback circuitry including: a first transistor having a first current path terminal, a second current path terminal, and a control terminal, the control terminal of the first transistor coupled to the driver circuitry and the control terminal of the switch, the first current path terminal of the first transistor coupled to the first current path terminal of the switch; and a comparison circuit including an input and an output, the input of the comparison circuit coupled to the second current path terminal of the first transistor.

Example 24. The charge pump of example 23, where the switch is a first switch, the capacitor is a first capacitor, and the second charge pump terminal is further configured to be coupled to a second capacitor, the charge pump further including: a second switch having a current path coupled between the second charge pump terminal and the first common terminal; a third charge pump terminal configured to be coupled to the second capacitor; and a third switch having a current path, the current path of the third switch coupled between the third charge pump terminal and a third common terminal.

Example 25. The charge pump of one of examples 23 or 24, further including: a fourth switch having a current path coupled between the first charge pump terminal and the first common terminal; a fifth switch having a current path coupled between the second charge pump terminal and the second common terminal; a sixth switch having a current path coupled between the first charge pump terminal and a fourth common terminal; a seventh switch having a current path coupled between the second charge pump terminal and the fourth common terminal; an eighth switch having a current path coupled between the second charge pump terminal and the third common terminal; and a ninth switch having a current path coupled between the third charge pump terminal and the fourth common terminal.

Example 26. The charge pump of one of examples 23 to 25, where the second common terminal and the third common terminal are coupled to power a speaker driver.

Example 27. A circuit including: a high-side transistor having a first current path terminal, a second current path terminal, and a control terminal, the first current path terminal coupled to a supply terminal; a first driver having an input and an output, the output of the first driver coupled to the control terminal of the high-side transistor; a low-side transistor having a first current path terminal, a second current path terminal, and a control terminal, the first current path terminal of the low-side transistor coupled to the second current path terminal of the high-side transistor, the second current path terminal of the low-side transistor coupled to a common terminal; a second driver having an input and an output, the output of the second driver coupled to the control terminal of the low-side transistor; and feedback circuitry coupled to the output of the first driver and the control terminal of the high-side transistor, the feedback circuitry including: a first transistor having a first current path terminal, a second current path terminal, and a control terminal, the control terminal of the first transistor coupled to the output of the first driver, the first current path terminal of the first transistor coupled to the first current path terminal of the high-side transistor; and a comparison circuit including an input and an output, the input of the comparison circuit coupled to the second current path terminal of the first transistor. 28. The circuit of claim 27, where the circuit is included in a switching regulator.

Example 29. The circuit of one of examples 27 or 28, where the circuit is included in a class D amplifier.

While this disclosure has been described with reference to illustrative embodiments, this description is not limiting. Various modifications and combinations of the illustrative embodiments, as well as other embodiments, will be apparent to persons skilled in the art upon reference to the description.

What is claimed is:

1. An apparatus comprising:
a driver including:
a first inverter having an input and an output; and
a second inverter having an input and an output, the input of the second inverter coupled to the output of the first inverter;
a first transistor of a first type, the first transistor having a first current path terminal, a second current path terminal, and a control terminal, the control terminal of the first transistor coupled to the output of the second inverter;
a second transistor of the first type, the second transistor having a first current path terminal, a second current path terminal, and a control terminal, the control terminal of the second transistor coupled to the output of the second inverter and the control terminal of the first transistor, the second current path terminal of the second transistor coupled to the second current path terminal of the first transistor; and
a third transistor of the first type, the third transistor having a control terminal and a first current path terminal, the control terminal of the first transistor coupled to the output of the first inverter and the input of the second inverter, the first current path terminal of the third transistor coupled to the first current path terminal of the second transistor.

2. The apparatus of claim 1, wherein the second transistor and the first transistor are a matching pair of transistors.

3. The apparatus of claim 1, wherein the first transistor and the second transistor are n-channel metal oxide semiconductor transistors and the second current path terminals of the first and second transistors are source terminals.

4. The apparatus of claim 1, further comprising a resistor coupled between the output of the second inverter and the control terminals of the first and second transistors.

5. The apparatus of claim 1, further comprising a comparison circuit including an input and an output, the input of the comparison circuit coupled to the first current path terminal of the third transistor.

6. The apparatus of claim 5, further including a flip flop having a clock input coupled to the output of the comparison circuit.

7. The apparatus of claim 6, wherein the flip flop has a data input coupled to a supply voltage terminal, and a reset input coupled to the output of the first inverter, the input of the second inverter, and the control terminal of the first transistor.

8. The apparatus of claim 7, further comprising a resistor coupled between the supply voltage terminal and the second current path terminal of the third transistor.

9. The apparatus of claim 5, wherein the comparison circuit is a Schmitt Trigger buffer.

10. The apparatus of claim 5, wherein the comparison circuit comprises an inverter.

11. The apparatus of claim 5, further including:
a fourth transistor of a second type, the fourth transistor having a control terminal, a first current path terminal, and a second current path terminal, the control terminal of the fourth transistor coupled to the control terminal of the third transistor, the output of the first inverter, and the input of the second inverter, the second current path terminal of the fourth transistor coupled to the input of the comparison circuit; and
a fifth transistor of the second type, the fifth transistor having a control terminal, a first current path terminal, and a second current path terminal, the control terminal of the fifth transistor coupled to the control terminals of the first and second transistors and the output of the second inverter, the first current path terminal of the fifth transistor coupled to the first current path terminal of the fourth transistor, and the second current path terminal of the fifth transistor coupled to the input of the comparison circuit.

12. The apparatus of claim 11, wherein the first type is n-type, and wherein the second type is p-type.

13. The apparatus of claim 12, further including a resistor coupled between the first current path terminal of the fourth transistor and the first current path terminal of the fifth transistor.

14. The apparatus of claim 1, further comprising a fourth transistor having a first current path terminal and a second current path terminal, the first current path terminal of the fourth transistor coupled to the control terminals of the first and second transistors, the second current path terminal of the fourth transistor coupled to the second current path terminals of the first and second transistors.

15. The apparatus of claim 1, wherein the first transistor and the second transistor are p-channel transistors.

16. An apparatus comprising:
a first switch;
second and third switches coupled in series;
a driver configured to:
receive a first control signal;
provide a second control signal having an edge having a first slope to control terminals of the first and second switches based on the first control signal; and
provide a third control signal having a second edge having a second slope to a control terminal of the third switch based on the first control signal, the second slope being higher than the first slope.

17. The apparatus of claim 16, wherein the second and third control signals are complementary signals.

18. The apparatus of claim 16, further comprising:
a comparison circuit having an input coupled to the third switch; and
a flag terminal configured to provide a voltage indicative of a state of the first switch based on an output of the comparison circuit.

19. The apparatus of claim 18, further comprising a fourth switch coupled to a control terminal of the first switch, the fourth switch having a control terminal coupled to the flag terminal.

20. The apparatus of claim 18, further including a controller configured to adjust the first control signal responsive to the voltage.

21. The apparatus of claim 20, wherein the controller is configured to adjust the first control signal responsive to the voltage and an edge of a clock signal.

22. The apparatus of claim 16, wherein the second and third switches are n-type transistors, wherein the second control signal has a lower slope than the first control signal, and wherein the third control signal is an inverted version of the first control signal.
